(19) United States
(12) Patent Application Publication
(10) Pub. No.: US 2026/0221715 A1
(43) Pub. Date: Jul. 30, 2026

(54) SEMICONDUCTOR LASER DEVICE

(71) Applicant: ams-OSRAM International GmbH, Regensburg (DE)

(72) Inventors: Nicole BERNER, Walderbach (DE); Andreas FRÖHLICH, Regensburg (DE); Erik HEINEMANN, Regensburg (DE); Jan MARFELD, Regensburg (DE); Jörg Erich SORG, Regensburg (DE)

(73) Assignee: ams-OSRAM International GmbH, Regensburg (DE)

(21) Appl. No.: 19/146,423

(22) PCT Filed: Jan. 9, 2024
(86) PCT No.: PCT/EP2024/050357

§ 371 Date: Jul. 8, 2025

(30) Foreign Application Priority Data
Jan. 11, 2023 (DE) 10 2023 100 478.6

(51) Int. Cl. H01S 5/023

(52) U.S. Cl. CPC H01S 5/023

(57) ABSTRACT

The invention relates to a semiconductor laser device including at least one semiconductor laser which is secured to a mounting surface of a mounting support via an intermediate support, wherein the intermediate support has a securing surface, to which the at least one semiconductor laser is secured; the intermediate support has a mounting lateral surface which runs perpendicularly to the securing surface and at which the intermediate support (2) is secured to the mounting surface of the mounting support; and the intermediate support has at least two electric contact surfaces, said at least two electric contact surfaces being connected to a respective connection surface of the mounting support in an electrically conductive manner and running parallel to the mounting surface of the mounting support.

### CROSS-REFERENCE TO RELATED APPLICATIONS

The present application is a national stage entry from International Application No. PCT/EP2024/050357, filed on Jan. 9, 2024, published as International Publication No. WO 2024/149737 A1 on Jul. 18, 2024, and claims priority to German Patent Application No. 10 2023 100 478.6, filed Jan. 11, 2023, the disclosures of all of which are hereby incorporated by reference in their entireties.

### FIELD

The present application relates to a semiconductor laser device with at least one semiconductor laser.

### BACKGROUND

For various laser applications, housing concepts are required with which the radiation of one or more lasers can be reliably achieved with a compact design.

One task is to specify a semiconductor laser device that is compact and emits in a lateral direction, for example.

This task is solved, inter alia, by a semiconductor laser device with the features of claim 1. Further configurations and expediencies are the subject of the dependent claims.

### SUMMARY

A semiconductor laser device with at least one semiconductor laser specified. The semiconductor laser device is configured, for example, as a surface-mounted device (smd). The semiconductor laser is, for example, an edge-emitting semiconductor laser with one or more emission regions. An emission region is, for example, a ridge-shaped region (also referred to as a ridge), wherein in the case of several emission regions, at least some or all emission regions may be electrically contactable independently of one another, for example. For example, the semiconductor laser is configured for generating radiation in the red, green or blue spectral range. Alternatively or additionally, the semiconductor laser may also be provided for generating radiation in the ultraviolet or infrared spectral range.

According to at least one embodiment of the semiconductor laser device, the semiconductor laser is attached to a mounting surface of a mounting carrier via an intermediate carrier. Such an arrangement is also referred to as a COSA (Chip On Submount Assembly). For example, the intermediate carrier comprises a fastening surface to which the at least one semiconductor laser is attached. The semiconductor laser itself is configured in particular as a semiconductor chip and does not comprise any housing per se.

According to at least one embodiment of the semiconductor laser device, the intermediate carrier comprises a mounting side surface which extends perpendicular to the fastening surface and at which the intermediate carrier is attached to the mounting surface of the mounting carrier. The fastening surface, to which the at least one semiconductor laser is attached, therefore runs perpendicular to the mounting surface of the mounting carrier. The mounting side surface is used to attach the intermediate carrier to the mounting carrier and can optionally also comprise one or more electrical contact surfaces for the electrical contacting of the intermediate carrier.

In the context of the present application, the terms “perpendicular” and “parallel” also include small production-related tolerances, for example of at most 10° or at most 5°.

According to at least one embodiment of the semiconductor laser device, the intermediate carrier comprises at least two electrical contact surfaces, wherein the at least two electrical contact surfaces are each electrically conductively connected to a connection surface of the mounting carrier and extend parallel to the mounting surface of the mounting carrier. In particular, all electrical contact surfaces that are configured for the electrical contacting of the intermediate carrier with associated connection surfaces of the mounting carrier may run parallel to the mounting surface of the mounting carrier. This simplifies the process of producing an electrical contact between the electrical contact surfaces of the intermediate carrier and the connection surfaces of the mounting carrier.

In at least one embodiment, the semiconductor laser device comprises at least one semiconductor laser which is attached to a mounting surface of a mounting carrier via an intermediate carrier, wherein the intermediate carrier comprises a fastening surface to which the at least one semiconductor laser is attached. The intermediate carrier comprises a mounting side surface which extends perpendicular to the fastening surface and at which the intermediate carrier is attached to the mounting surface of the mounting carrier. The intermediate carrier comprises at least two electrical contact surfaces, wherein the at least two electrical contact surfaces are each electrically conductively connected with a connection surface of the mounting carrier and run parallel to the mounting surface of the mounting carrier.

Both the electrical contacting of the semiconductor laser and the mechanical connection of the semiconductor laser with the mounting carrier are therefore made via the intermediate carrier. By arranging the electrical contact surfaces of the intermediate carrier parallel to the mounting surface of the mounting carrier, it is easier to produce an electrically conductive connection between the contact surfaces of the intermediate carrier and the associated connection surfaces of the mounting carrier.

According to at least one embodiment of the semiconductor laser device, a main emission direction of the at least one semiconductor laser runs obliquely or parallel to the mounting surface of the mounting carrier. In particular, the main emission direction in this case does not run perpendicular to the mounting surface of the mounting carrier. For example, an angle between the main emission direction and the mounting surface of the mounting carrier is at most 70° or at most 50° or at most 30°. Devices in which the radiation is emitted parallel to the mounting surface of the mounting carrier are also referred to as “sidelookers”.

According to at least one embodiment of the semiconductor laser device, the electrical contact surfaces are formed by a contact coating of the intermediate carrier, wherein the contact coating is guided onto the fastening surface of the intermediate carrier and wherein the contact coating comprises at least two connection surfaces on the fastening surface for the electrical contacting of the semiconductor laser. For example, at least one electrical contact surface, in particular exactly one electrical contact surface, is assigned to each connection surface on the fastening surface, or vice versa. The semiconductor laser can therefore be electrically contacted via the connection surfaces that are present on the fastening surface of the intermediate carrier. When producing, this is expediently done before the intermediate carrier is attached to the mounting carrier.

In contrast, the electrical contact between the intermediate carrier and the mounting carrier is not made on the fastening surface, but on the mounting side surface of the intermediate carrier and/or on the side surface of the mounting carrier opposite the mounting side surface.

More than one semiconductor laser can also be attached to the intermediate carrier. For example, the intermediate carrier comprises contact surfaces and connection surfaces for exactly two or for more than two semiconductor lasers.

According to at least one embodiment of the semiconductor laser device, the at least one semiconductor laser comprises a plurality of emission regions that are controllable independently of one another. For example, the emission regions are arranged next to each other parallel to the fastening surface of the intermediate carrier. In relation to the mounting surface of the mounting carrier, the emission regions are therefore arranged one above the other.

In deviation from this, however, only a single emission region or several emission regions that can only be electrically contacted together can also be provided.

According to at least one embodiment of the semiconductor laser device, at least one of the electrical contact surfaces is arranged on the mounting side surface. An electrical contact surface arranged on the mounting side surface can, for example, be electrically connected to the associated connection surface on the mounting carrier via a soldered connection or via sintering.

In particular, two or more electrical contact surfaces or even all electrical contact surfaces of the intermediate carrier can also be arranged on the mounting side surface. In this case, the contact coating is therefore structured into at least two electrical contact surfaces on the mounting side surface, which are not directly connected to each other in an electrically conductive manner.

According to at least one embodiment of the semiconductor laser device, at least one of the electrical contact surfaces is arranged on a side surface of the intermediate carrier opposite the mounting side surface. Such an electrical contact surface can, for example, be electrically connected to the associated connection surface of the mounting carrier via a wire bond connection. In particular, two or more electrical contact surfaces or even all electrical contact surfaces may be arranged on the side surface opposite the mounting side surface. In this case, the mounting side surface is used exclusively for the mechanical connection of the intermediate carrier with the mounting carrier, but not for the electrical contact between the intermediate carrier and the mounting carrier.

According to at least one embodiment of the semiconductor laser device, at least one of the electrical contact surfaces is arranged on the mounting side surface and at least one of the contact surfaces is arranged on the side surface of the intermediate carrier opposite the mounting side surface. The electrical contact surfaces may thus be distributed over two side surfaces of the intermediate carrier. For example, electrical contact surfaces of a first polarity (for example n-contact surfaces) can be arranged on the mounting side surface and electrical contact surfaces of a second polarity (for example p-contact surfaces) different from the first polarity can be arranged on the opposite side surface or vice versa.

According to at least one embodiment of the semiconductor laser device, all electrical contact surfaces of the intermediate carrier are arranged either only on the mounting side surface or only on a side surface of the intermediate carrier opposite the mounting side surface. In this case, it is sufficient if the contact coating is arranged on exactly two outer surfaces of the intermediate carrier, namely on the fastening surface and on one of the side surfaces. If all electrical contact surfaces are arranged on the mounting side surface, there is no need to produce wire bond connections for the connection between the mounting carrier and the intermediate carrier. If, on the other hand, all electrical contact surfaces are arranged on the side surface opposite the mounting side surface, the electrical contact can be produced exclusively via wire bond connections. This allows a comparatively high degree of flexibility in the positioning of the connection surfaces on the mounting carrier.

According to at least one embodiment of the semiconductor laser device, the semiconductor laser device comprises a further intermediate carrier with a further fastening surface. Features described in connection with the intermediate carrier can also be used for the further intermediate carrier.

For example, the further intermediate carrier comprises a further mounting side surface which runs perpendicular to the further fastening surface and at which the further intermediate carrier is attached to the mounting surface of the mounting carrier. The further intermediate carrier comprises, for example, at least two further electrical contact surfaces, wherein the at least two further electrical contact surfaces are electrically conductively connected with the mounting carrier and extend parallel to the mounting surface of the mounting carrier. A further semiconductor laser is attached to the further fastening surface, for example.

Thus, the intermediate carrier and the further intermediate carrier are arranged next to each other along the mounting surface of the mounting carrier.

According to at least one embodiment of the semiconductor laser device, the fastening surface and the further fastening surface face each other. As a result, a particularly small distance between the semiconductor laser and the further semiconductor laser can be achieved. In particular, the fastening surface and the further fastening surface run parallel to each other.

According to at least one embodiment of the semiconductor laser device, the semiconductor laser on the intermediate carrier and the further semiconductor laser on the further intermediate carrier each comprise a plurality of emission regions, the emission regions of the semiconductor laser and of the further semiconductor laser being located together within an exit region in the form of an ellipse with a longitudinal axis and a transverse axis. The emission regions of more than two semiconductor lasers on the intermediate carrier and/or of more than two semiconductor lasers on the further intermediate carrier, for example of a total of exactly three semiconductor lasers, can also be located within the exit area.

For example, the longitudinal axis is less than or equal to 1000 μm or less than or equal to 500 μm and/or the transverse axis is less than or equal to 200 μm or less than or equal to 100 μm. Such a compact arrangement of the emission regions simplifies beam shaping by downstream optical elements.

According to at least one embodiment of the semiconductor laser device, the longitudinal axis runs perpendicular to the mounting surface of the mounting carrier. The transverse axis may run parallel to the mounting surface of the mounting carrier.

According to at least one embodiment of the semiconductor laser device, the semiconductor laser device comprises a cover which is attached to the mounting carrier and by means of which the semiconductor laser device is hermetically sealed. For example, the cover is made of a material that is transmissive to the radiation emitted by the semiconductor laser device during operation. For example, the cover comprises a glass or a plastics material.

A semiconductor laser device described here is particularly suitable for use as a compact laser light source in portable devices, for example for projection applications, head-up displays, augmented reality displays or virtual reality displays.

Features described in connection with at least one embodiment may also be combined with other features described in connection with at least one embodiment, as long as these features are not mutually exclusive.

Further configurations and expediencies will become apparent from the following description of the exemplary embodiments in conjunction with the figures.

### BRIEF DESCRIPTION OF THE DRAWINGS

In the Figures:

FIG. 1A shows a side view of an exemplary embodiment of a semiconductor laser device;

FIG. 1B shows an associated perspective view of a semiconductor laser device with an optional cover;

FIGS. 1C and 1D each show two different perspective views of an intermediate carrier according to an exemplary embodiment;

FIG. 1E shows a schematic representation of an intermediate carrier as shown in FIGS. 1C and 1D with semiconductor lasers mounted thereon;

FIG. 2 shows a side view of another exemplary embodiment of a semiconductor device; and

FIGS. 3A to 3D show a further exemplary embodiment of a semiconductor laser device, wherein FIG. 3A shows a perspective view of the semiconductor laser device, FIG. 3B shows a perspective view of the semiconductor laser device with an optional cover, and FIGS. 3C and 3D show two different perspective views of an intermediate carrier.

### DETAILED DESCRIPTION

The figures are schematic representations and are therefore not necessarily true to scale. In particular, comparatively small elements or layer thicknesses may be shown in exaggerated size for improved representation and/or better understanding. Elements that are identical, similar or have the same effect are each provided with the same reference symbols in the figures.

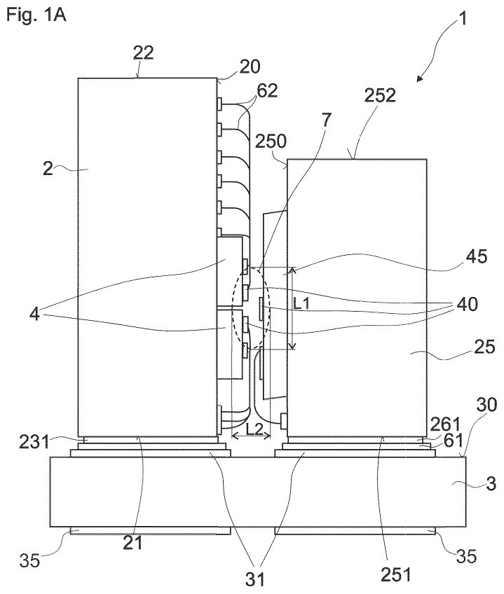

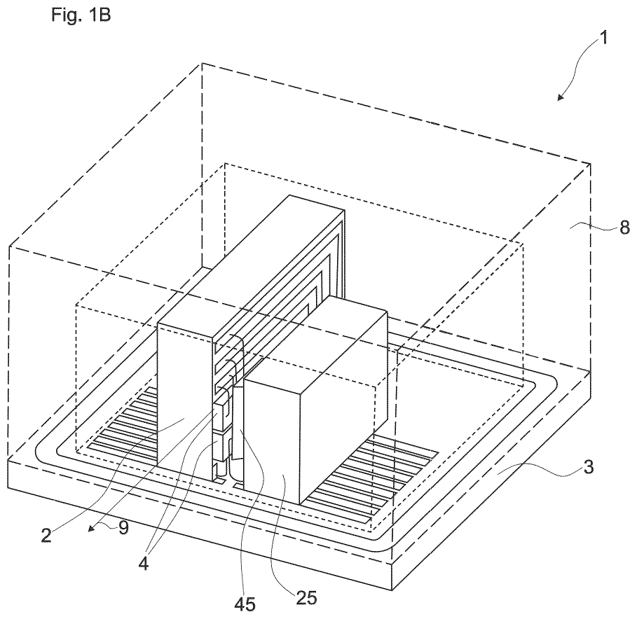

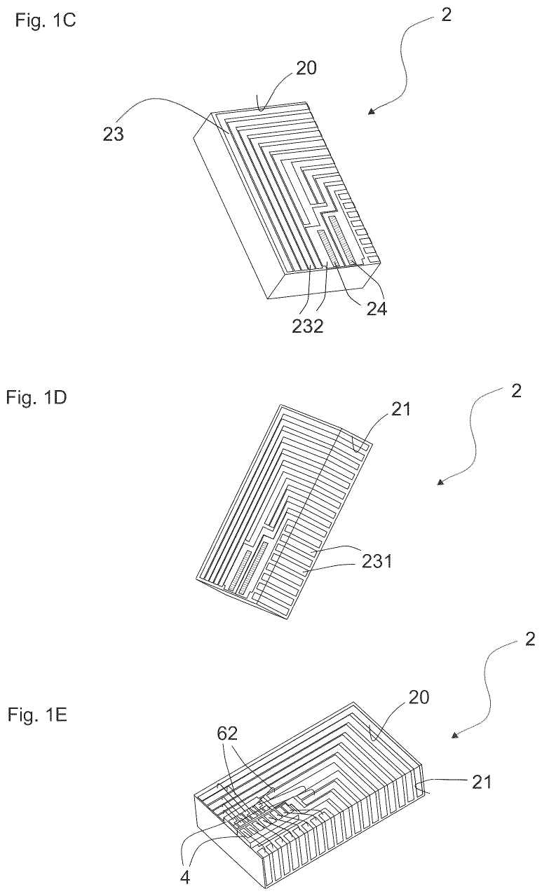

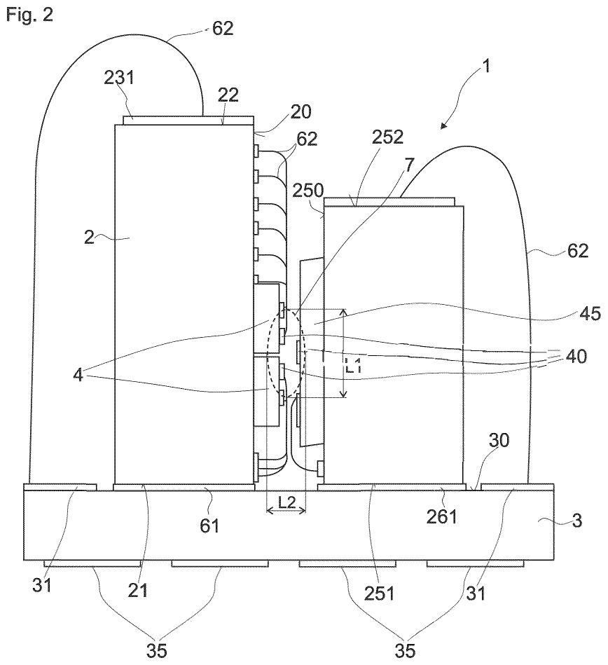

In the exemplary embodiment shown in FIGS. 1A to 1E, the semiconductor laser device 1 comprises two semiconductor lasers 4, which are attached to a mounting surface 30 of a mounting carrier 3 via a common intermediate carrier 2. Deviating from this, only one semiconductor laser or more than two semiconductor lasers 4 may also be attached to the intermediate carrier 2.

The intermediate carrier 2 comprises a fastening surface 20 to which the semiconductor lasers 4 are attached. The intermediate carrier 2 comprises a mounting side surface 21 which runs perpendicular to the fastening surface 20 and at which the intermediate carrier 2 is attached to the mounting surface 30 of the mounting carrier 3.

The intermediate carrier 2 comprises several electrical contact surfaces 231, wherein the electrical contact surfaces 23 are each electrically conductively connected with a connection surface 31 of the mounting carrier 3. The electrical contact surfaces 231 run parallel to the mounting surface 30 of the mounting carrier 3.

In the exemplary embodiment shown in FIG. 1A, the electrical contact surfaces 231 are located on the mounting side surface 21 of the intermediate carrier 2, so that the electrically conductive connection between the electrical contact surfaces 231 and the associated connection surfaces 31 of the mounting carrier 3 can be made via a connection means 61, for example a solder. Alternatively, the intermediate carrier 2 may be attached to the mounting carrier 3 by sintering.

A main emission direction 9 of the semiconductor lasers 4 runs parallel to the mounting surface 30 of the mounting carrier 3 (see FIG. 1B). Deviating from this, the main emission direction 9 can also run at an angle or perpendicular to the mounting surface 30 of the mounting carrier 3. For example, an angle between the main emission direction 9 and the mounting surface 30 of the mounting carrier 3 is at most 70° or at most 50° or at most 30°.

The semiconductor lasers 4 are each electrically conductively connected to connection surfaces 232 via wire bond connections 62. The electrical contact surfaces 231 and the connection surfaces 232 are formed by a structured contact coating 23 of the intermediate carrier 2.

As FIGS. 1C and 1D illustrate, the contact coating 23 is formed on exactly two outer surfaces of the intermediate carrier 2, namely on the fastening surface 20 and on the mounting side surface 21.

The electrical connection of the semiconductor lasers 4 with the connection surfaces 232 on the fastening surface 20 is illustrated in FIG. 1E. The semiconductor lasers 4 are each arranged on a laser mounting area 24 of the intermediate carrier 2 (see FIG. 1C).

In the exemplary embodiment shown, the intermediate carrier 2 is configured for two semiconductor lasers 4, each with eight emission regions 40. For individual control of the emission regions 40, this results in 16 contact surfaces 231 for the individual emission regions 40 in the form of ridges (for example p contact surfaces) and a counter-contact with the other polarity for each semiconductor laser 4, so that the mounting side surface 21 comprises a total of 18 contact surfaces 231.

When producing the semiconductor laser device 1, the semiconductor lasers 4 can first be mounted on the intermediate carrier 2, for example by soldering. At the same time, an electrically conductive connection is made between the laser mounting areas 24 and the semiconductor lasers 4. On the opposite side of the semiconductor lasers 4, the semiconductor lasers 4 are electrically contacted via wire bond connections 62 with the connection surfaces 232 on the fastening surface 20 of the intermediate carrier 2.

When mounting the intermediate carrier 2 with the semiconductor lasers 4 on the mounting surface 30 of the mounting carrier 3, an electrically conductive connection is simultaneously produced between the connection surfaces 31 of the mounting carrier and the contact surfaces 231 of the intermediate carrier. All contact surfaces 231 are located on the mounting side surface 21 of the intermediate carrier 2. In this exemplary embodiment, wire bond connections are therefore only provided for electrical contacting of the semiconductor lasers 4 to the intermediate carrier 2.

In particular, the contact surfaces 231 for both polarities of the semiconductor lasers 4 are arranged on the same side, in the exemplary embodiment shown on the mounting side surface 251.

A ceramic, such as aluminum nitride, is suitable for the intermediate carrier 2 and/or the mounting carrier 3. Ceramic materials comprise an advantageously high thermal conductivity. Alternatively, a semiconductor material can also be used, for example.

In the exemplary embodiment shown, the semiconductor laser device 1 further comprises a further intermediate carrier 25, wherein the further intermediate carrier comprises a further fastening surface 250 for mounting a further semiconductor laser 45 and a further mounting side surface 251 extending perpendicularly to the further fastening surface 250. On a side of the further intermediate carrier 25 opposite the further mounting side surface 251, a further side surface 252 is formed which, like the side surface 22 of the intermediate carrier 2 opposite the mounting side surface 21 in this exemplary embodiment, is free of the contact coating 23.

The fastening surface 20 and the further fastening surface 250 face each other, so that the semiconductor lasers 4 and the further semiconductor laser 45 can be arranged at a comparatively small distance from each other.

Preferably, the emission regions 40 of the semiconductor lasers 4 on the intermediate carrier 2 and of the further semiconductor laser 45 on the further intermediate carrier 25 are located together within an exit region 7 in the form of an ellipse with a longitudinal axis L1 and a transverse axis L2. The longitudinal axis L1 is preferably less than 1000 μm, or less than 500 μm or less than 300 μm. The transverse axis L2 is preferably less than 200 μm or less than 100 μm or less than 60 μm.

Such a compact arrangement of the emission regions simplifies the use of particularly compact downstream optical elements. The longitudinal axis L1 runs perpendicular to the mounting surface 30 of the mounting carrier 3.

For example, the semiconductor lasers 4 and the further semiconductor laser 45 taken together emit in three different spectral ranges, for example in the red, green and blue spectral range, so that the semiconductor laser device 1 represents an RGB laser module, in particular in a surface-mountable and/or hermetically sealed configuration.

In particular in a configuration with several emission regions per semiconductor laser 4, 45, a large number of emission regions 40 can be provided within a small coupling-out area by the arrangement described, wherein the main emission direction 9 runs parallel to the mounting surface 30 of the mounting carrier 3. However, the main emission direction 9 can also run obliquely or perpendicular to the mounting surface 30.

In particular, all external electrical contacts 35 of the semiconductor laser device 1 can be arranged on a side of the mounting carrier 3 opposite the mounting surface 30, so that the semiconductor laser device 1 as a whole is designed as a surface-mounted device. The external contacts 35 can, for example, each be electrically conductively connected via vias through the mounting carrier 3 with the associated connection surfaces 31 of the mounting carrier 3.

As shown in FIG. 1B, the semiconductor laser device may further optionally comprise a cover 8 which is attached to the mounting carrier 3 and by means of which the semiconductor laser device 1 is hermetically sealed. For example, the cover 8 is formed by a glass or a plastics that is transmissive in the radiation ranges to be emitted by the semiconductor laser device.

Of course, the number of intermediate carriers 2, 25 and/or the number of semiconductor lasers 4, 45 per intermediate carrier 2, 25 and/or the number of emission regions 40 per semiconductor laser 4, 45 can be varied within wide limits.

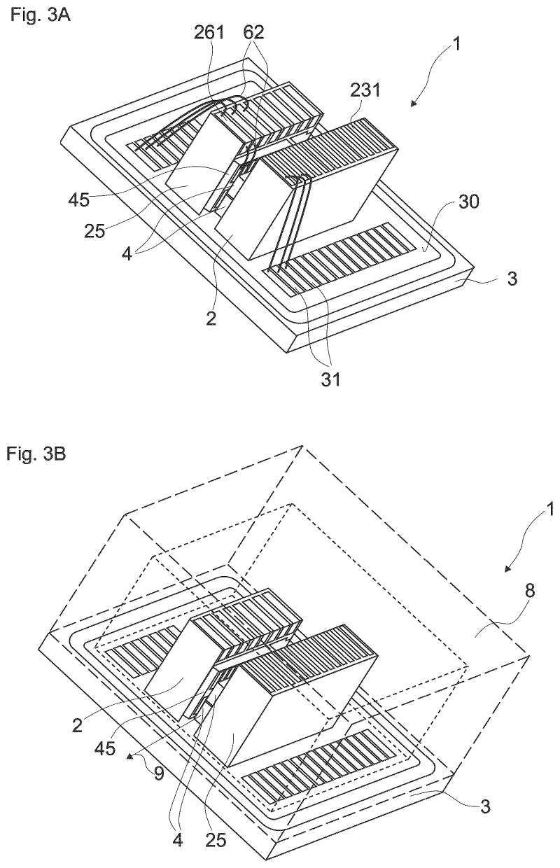

The exemplary embodiment shown in FIG. 2 essentially corresponds to the exemplary embodiment described with reference to FIGS. 1A to 1E.

In contrast to this, the electrical contact surfaces 231 are arranged on the side surface 22 opposite the mounting side surface 21. The electrically conductive connection between the electrical contact surfaces 231 and the associated connection surfaces 31 of the mounting carrier 3 is made in each case by means of a wire bond connection 62. In contrast, no electrical contacting of the intermediate carrier 2 is made on the mounting side surface 21. An electrically insulating material, for example an adhesive, can therefore also be used as the connection means 61.

In contrast to the exemplary embodiment shown in FIGS. 1A to 1E, the arrangement of the contact surfaces 231 solely on the side surface 22 increases the freedom with regard to the positioning of the connection surfaces 31 on the mounting surface 30. Fine adjustment of the position of the intermediate carrier 2 and, if necessary, of the further intermediate carrier 25 on the mounting carrier when producing the semiconductor laser device 1 is thus simplified.

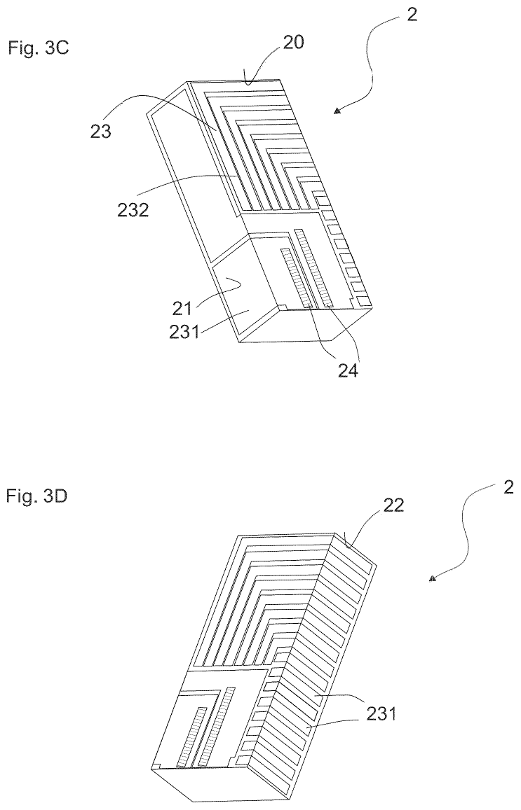

The exemplary embodiment shown in FIGS. 3A to 3D essentially corresponds to the exemplary embodiment described with reference to FIGS. 1A to 1E.

In contrast to this, the intermediate carrier 2 comprises contact surfaces 231 both on the mounting side surface 21 and on the opposite side surface 22. The contact coating 23 thus extends over a total of three outer surfaces of the intermediate carrier 2. In the exemplary embodiment shown, contact surfaces 231 of one polarity are arranged on each of the side surfaces. However, this is not absolutely necessary.

The contact surfaces 231 on the mounting side surface 21 are connected with the connection surfaces 232, which form the laser mounting areas 24. The electrical contact of the contact surfaces 231 on the side surface 22 opposite the mounting side surface 21 is again made via wire bond connections 62. For improved visualization, only some wire bond connections 62 are drawn in FIG. 3A. With such a three-sided metallized intermediate carrier 2, the total required contact surfaces 231 can be divided between two side surfaces of the intermediate carrier 2. The expansion of the intermediate carrier 2 along the main emission direction 9 can thus be reduced while maintaining the same size of the contact surfaces. As a result, even smaller designs can be realized.

The explanations regarding the intermediate carrier 2 apply analogously to the further intermediate carrier 25 with the further contact surfaces 261.

However, as in the exemplary embodiment described in FIGS. 1A to 1E, the position of the intermediate carrier 2 and the further intermediate carrier 25 on the mounting carrier 3 is predetermined due to the contact surfaces 231 arranged on the mounting side surface 21, so that the intermediate carriers 2, 25 can only be moved relative to each other to a very limited extent during the production of the semiconductor laser device 1, in particular along the main emission direction 9.

The invention is not limited by the description based on the exemplary embodiments. Rather, the invention includes any new feature as well as any combination of features, which includes in particular any combination of features in the claims, even if this feature or combination itself is not explicitly stated in the claims or the exemplary embodiments.

1. A semiconductor laser device comprising at least one semiconductor laser which is attached to a mounting surface of a mounting carrier via an intermediate carrier, wherein
the intermediate carrier comprises a fastening surface to which the at least one semiconductor laser is attached;
the intermediate carrier comprises a mounting side surface which extends perpendicular to the fastening surface and at which the intermediate carrier is attached to the mounting surface of the mounting carrier; and
the intermediate carrier comprises at least two electrical contact surfaces, wherein the at least two electrical contact surfaces are each electrically conductively connected to a connection surface of the mounting carrier and extend parallel to the mounting surface of the mounting carrier;
the semiconductor laser device comprises a further intermediate carrier with a further fastening surface;
the further intermediate carrier comprises a further mounting side surface which extends perpendicularly to the further fastening surface and at which the further intermediate carrier is attached to the mounting surface of the mounting carrier;
the further intermediate carrier comprises at least two further electrical contact surfaces, wherein the at least two further electrical contact surfaces are electrically conductively connected with the mounting carrier and extend parallel to the mounting surface of the mounting carrier;
a further semiconductor laser is attached to the further fastening surface; and
the fastening surface and the further fastening surface face each other.

2. The semiconductor laser device according to claim 1,
wherein
a main emission direction of the at least one semiconductor laser extends obliquely or parallel to the mounting surface of the mounting carrier; and
the electrical contact surfaces are formed by a contact coating of the intermediate carrier, wherein the contact coating is guided onto the fastening surface of the intermediate carrier and wherein the contact coating comprises at least two connection surfaces on the fastening surface for the electrical contacting of the semiconductor laser.

3. The semiconductor laser device according to claim 1, wherein the at least one semiconductor laser comprises a plurality of emission regions which are controllable independently of one another.

4. The semiconductor laser device according to claim 1, wherein at least one of the electrical contact surfaces is arranged on the mounting side surface.

5. The semiconductor laser device according to claim 1, wherein at least one of the electrical contact surfaces is arranged on a side surface of the intermediate carrier opposite the mounting side surface.

6. The semiconductor laser device according to claim 5, wherein at least one of the electrical contact surfaces is arranged on the mounting side surface and at least one of the contact surfaces is arranged on the side surface of the intermediate carrier.

7. The semiconductor laser device according to claim 1, wherein all electrical contact surfaces of the intermediate carrier are arranged either on the mounting side surface or on a side surface of the intermediate carrier opposite the mounting side surface.

8. The semiconductor laser device according to claim 1, wherein the semiconductor laser device comprises a cover which is attached to the mounting carrier and by means of which the semiconductor laser device is hermetically sealed.

9. The semiconductor laser device according to claim 1, wherein the semiconductor laser device is configured as a surface mounted device.

10. The semiconductor laser device according to claim 1,
wherein the semiconductor laser on the intermediate carrier and the further semiconductor laser on the further intermediate carrier each comprise a plurality of emission regions, wherein
the emission regions of the semiconductor laser and of the further semiconductor laser are located together within an exit region in the form of an ellipse with a longitudinal axis and a transverse axis, the longitudinal axis being less than 1000 μm and the transverse axis being less than 200 μm.

11. The semiconductor laser device according to claim 10, wherein the longitudinal axis is less than 500 μm and the transverse axis is less than 100 μm.

12. The semiconductor laser device according to claim 10, wherein the longitudinal axis runs perpendicular to the mounting surface of the mounting carrier.
